(19) United States
(12) Patent Application Publication
(10) Pub. No.: US 2026/0129889 A1
(43) Pub. Date: May 7, 2026

(54) SEMICONDUCTOR DEVICE

(71) Applicant: Mitsubishi Electric Corporation, Tokyo (JP)

(72) Inventors: Masaki SUDO, Tokyo (JP); Masanori TSUKUDA, Tokyo (JP); Takuya YOSHIDA, Fukuoka (JP); Shunsuke SAKAMOTO, Tokyo (JP); Yosuke NAKANISHI, Tokyo (JP)

(73) Assignee: Mitsubishi Electric Corporation, Tokyo (JP)

(21) Appl. No.: 19/367,248

(22) Filed: Oct. 23, 2025

(30) Foreign Application Priority Data
Nov. 6, 2024 (JP) 2024-194083

(51) Int. Cl. H10D 12/00; H01L 23/31

(52) U.S. Cl. CPC H10D 12/416; H10D 12/481; H10W 74/137

(57) ABSTRACT

A semiconductor device includes a collector electrode, a collector-side element trench structure, a collector-side gate pad, and a collector-side terminal trench structure. A side surface of the semiconductor substrate and the collector electrode surround the collector-side gate pad in a planar view, and the collector-side terminal trench structure penetrates the collector layer on the side surface side of the semiconductor substrate with respect to the connecting portion between the collector electrode and the collector layer in a cross-sectional view.

### BACKGROUND

### Technical Field

The present disclosure relates to a semiconductor device.

### Description of the Background Art

There are proposed semiconductor devices each including: an emitter-side gate electrode forming a channel on an emitter electrode side that is the front side; and a collector-side gate electrode forming a channel on a collector electrode side that is the back side. Various techniques have been proposed for such semiconductor devices having a double-sided gate structure.

For example, Japanese Patent Application Laid-Open No. 2010-123667 proposes a configuration in which a collector-side lead frame for electrically connecting to the outside is connected, by solder, to a collector-side gate pad disposed on the back surface side of a semiconductor substrate. With such a configuration, it is possible to form a channel on the back surface side of the semiconductor substrate by applying a voltage from outside to the collector-side gate electrode via the collector-side lead frame and the collector-side gate pad.

However, there are cases where, during the manufacturing process, the solder connecting the collector-side gate pad and the collector-side lead frame leaks to a side surface of the semiconductor substrate. This causes a problem in that the collector-side lead frame and the side surface of the semiconductor substrate are electrically connected by the solder, and the leakage current of the collector-side gate increases.

### SUMMARY

The present disclosure has been made in view of the above problems, and aims to provide a technology that can reduce leakage current of the collector-side gate.

A semiconductor device according to the present disclosure includes: a semiconductor substrate having a front surface and a back surface on which an element region and a termination region surrounding the element region are defined; an emitter electrode disposed on the front surface side of the semiconductor substrate; an emitter-side element trench structure that is disposed on the front surface side of the semiconductor substrate in the element region, and includes an emitter-side gate electrode insulated from the emitter electrode; an emitter-side gate pad that is disposed on the front surface side of the semiconductor substrate in the termination region, is insulated from the emitter electrode, and is electrically connected to the emitter-side gate electrode; a collector electrode disposed on the back surface side of the semiconductor substrate; a collector-side element trench structure that is disposed on the back surface side of the semiconductor substrate in the element region, and includes a collector-side gate electrode insulated from the collector electrode; a collector-side gate pad that is disposed on the back surface side of the semiconductor substrate in the termination region, is insulated from the collector electrode, and is electrically connected to the collector-side gate electrode; and a collector-side terminal trench structure that is disposed on the back surface side of the semiconductor substrate in the termination region, and includes a collector-side terminal electrode, wherein the semiconductor substrate includes: a drift layer of a first conductivity type; a buffer layer of the first conductivity type that is disposed on the back surface side of the drift layer; and a collector layer of a second conductivity type that is disposed on the back surface side of the buffer layer, a side surface of the semiconductor substrate and the collector electrode surround the collector-side gate pad in a planar view, and the collector-side terminal trench structure penetrates the collector layer on the side surface side of the semiconductor substrate with respect to a connecting portion between the collector electrode and the collector layer in a cross-sectional view.

Leakage current of the collector-side gate can be reduced.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of the front side of a semiconductor device according to a first preferred embodiment;

FIG. 2 is a plan view illustrating a configuration of the back side of the semiconductor device according to the first preferred embodiment;

FIG. 3 is a cross-sectional view illustrating a configuration of the semiconductor device according to the first preferred embodiment;

FIG. 4 is a cross-sectional view illustrating a configuration of a semiconductor device according to a second preferred embodiment;

FIG. 5 is a cross-sectional view illustrating a configuration of a semiconductor device according to a third preferred embodiment;

FIG. 6 is a plan view illustrating a configuration of the back side of a semiconductor device according to a fourth preferred embodiment;

FIG. 7 is a cross-sectional view illustrating a configuration of the semiconductor device according to the fourth preferred embodiment;

FIG. 8 is a plan view illustrating a configuration of the back side of the semiconductor device according to the fourth preferred embodiment;

FIG. 9 is a cross-sectional view illustrating a configuration of the semiconductor device according to the fourth preferred embodiment;

FIG. 10 is a plan view illustrating a configuration of the back side of the semiconductor device according to the fourth preferred embodiment;

FIG. 11 is a cross-sectional view illustrating a configuration of the semiconductor device according to the fourth preferred embodiment;

FIG. 12 is a cross-sectional view illustrating a configuration of a semiconductor device according to a fifth preferred embodiment;

FIG. 13 is a cross-sectional view illustrating a configuration of a semiconductor device according to a sixth preferred embodiment;

FIG. 14 is a plan view illustrating a configuration of the back side of a semiconductor device according to a seventh preferred embodiment;

FIG. 15 is a plan view illustrating a configuration of the back side of a semiconductor device according to an eighth preferred embodiment;

FIG. 16 is a plan view illustrating a configuration of the back side of a semiconductor device according to a ninth preferred embodiment;

FIG. 17 is a cross-sectional view illustrating a configuration of a semiconductor device according to a tenth preferred embodiment;

FIG. 18 is a plan view illustrating a configuration of the back side of a semiconductor device according to an eleventh preferred embodiment;

FIG. 19 is a cross-sectional view illustrating a configuration of the semiconductor device according to the eleventh preferred embodiment;

FIG. 20 is a plan view illustrating a configuration of the back side of a semiconductor device according to a twelfth preferred embodiment;

FIG. 21 is a cross-sectional view illustrating a configuration of the semiconductor device according to the twelfth preferred embodiment;

FIG. 22 is a plan view illustrating a configuration of the front side of a semiconductor device according to a thirteenth preferred embodiment; and

FIGS. 23 and 24 are cross-sectional views each illustrating a configuration of the semiconductor device according to the thirteenth preferred embodiment.

### DESCRIPTION OF THE PREFERRED EMBODIMENTS

The following is a description of preferred embodiments, with reference to the accompanying drawings. The features described below in the respective preferred embodiments are examples, and all the features are not necessarily essential. Also, in the description below, similar components in a plurality of preferred embodiments are denoted by the same or similar reference signs, and different components are mainly explained. Further, in the description below, specific positions and directions such as “upper”, “lower”, “left”, “right”, “front”, and “back” do not necessarily match the actual positions and directions in implementation. Furthermore, in the following, the first conductivity type is the n-type, and the second conductivity type is the p-type. However, the first conductivity type may be the p-type, and the second conductivity type may be the n-type.

### First Preferred Embodiment

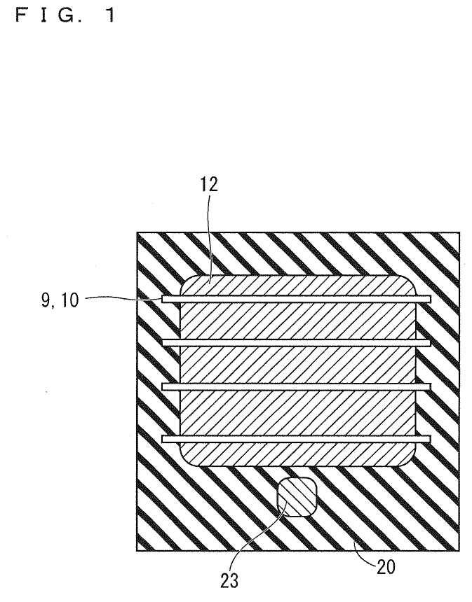

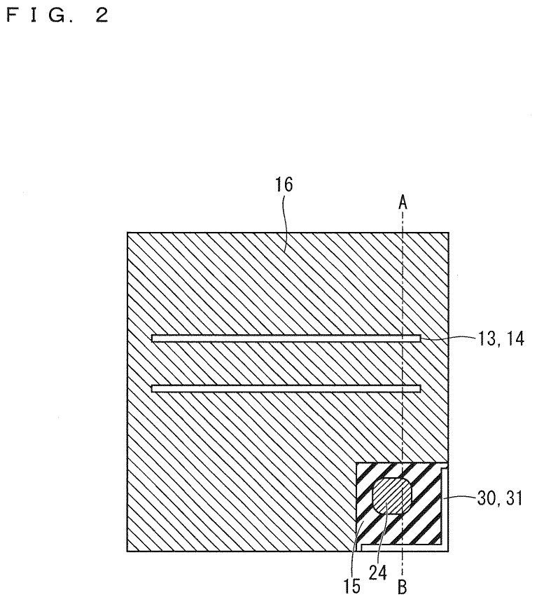

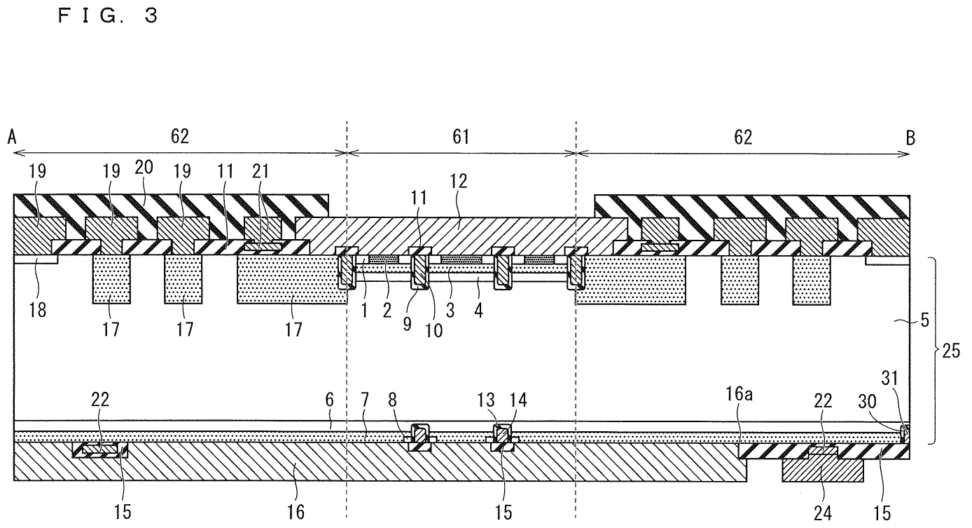

In the following, an example in which a semiconductor device according to a first preferred embodiment is an insulated gate bipolar transistor (IGBT) is described. FIGS. 1 and 2 are plan views illustrating configurations of the front side and the back side of the semiconductor device according to the first preferred embodiment, respectively. FIG. 3 is a cross-sectional view illustrating the configuration of the semiconductor device according to the first preferred embodiment, and specifically, is a cross-sectional view taken along the line A-B defined in FIG. 2.

As illustrated in FIG. 3, the semiconductor device according to the first preferred embodiment includes a semiconductor substrate 25, and the semiconductor substrate 25 has a front surface and a back surface on which an element region 61 and a termination region 62 surrounding the element region 61 are defined. A path for the principal current of the semiconductor device is formed in the element region 61, and the termination region 62 holds a withstand voltage in a lateral direction (the left-right direction in FIG. 3) of the semiconductor device. In the description below, the front surface and the back surface mean the front surface and the back surface of the semiconductor substrate 25.

Note that the semiconductor substrate 25 may be formed with normal silicon (Si), or may be formed with a wide bandgap semiconductor such as silicon carbide (SiC), gallium nitride (GaN), gallium oxide (Ga₂O₃), or diamond. In a case where the semiconductor substrate 25 is formed with a wide bandgap semiconductor, it is possible to stably operate the semiconductor device at high temperature and at high voltage, and increase the switching speed. The semiconductor substrate 25 may be formed with a normal semiconductor wafer, or may be formed with an epitaxially grown layer. In the following, the configuration of each of the element region 61 and the termination region 62 is described in detail.

### Element Region 61

In the element region 61, the semiconductor substrate 25 includes an n-type source layer 1, a p-type contact layer 2, a p-type base layer 3, an emitter-side n-type layer 4, an n-type drift layer 5, an n-type buffer layer 6, a p-type collector layer 7, and a collector-side n-type layer 8.

The emitter-side n-type layer 4 is disposed on the front surface side of the n-type drift layer 5, which is a withstand-voltage holding portion. The n-type impurity concentration in the emitter-side n-type layer 4 is equal to or higher than the n-type impurity concentration in the n-type drift layer 5. For example, the n-type impurity concentration in the n-type drift layer 5 is not lower than about 10¹² cm⁻³ and not higher than about 10¹⁴ cm⁻³, and the peak concentration of the n-type impurity in the emitter-side n-type layer 4 is not lower than about 10¹⁵ cm⁻³ and not higher than about 10¹⁷ cm⁻³.

The p-type base layer 3 is disposed on the front surface side of the emitter-side n-type layer 4. For example, the peak concentration of the p-type impurity in the p-type base layer 3 is about 10¹⁷ cm⁻³. The n-type source layer 1 and the p-type contact layer 2 are selectively disposed on the front surface side of the p-type base layer 3. For example, the peak concentration of the n-type impurity in the n-type source layer 1 is not lower than about 10¹⁸ cm⁻³ and not higher than about 10²¹ cm⁻³. The p-type impurity concentration in the p-type contact layer 2 is equal to or higher than the p-type impurity concentration in the p-type base layer 3.

The n-type buffer layer 6 is disposed on the back surface side of the n-type drift layer 5, which is a withstand-voltage holding portion. For example, the peak concentration of the n-type impurity in the n-type buffer layer 6 is not lower than about 10¹⁵ cm⁻³ and not higher than about 10¹⁸ cm⁻³. The p-type collector layer 7 is disposed on the back surface side of the n-type buffer layer 6. For example, the peak concentration of the p-type impurity in the p-type collector layer 7 is not lower than about 10¹⁷ cm⁻³ and not higher than about 10¹⁹ cm⁻³. The collector-side n-type layer 8 is selectively disposed on the back surface side of the p-type collector layer 7. For example, the peak concentration of the n-type impurity in the collector-side n-type layer 8 is not lower than about 10¹⁸ cm⁻³ and not higher than about 10²¹ cm⁻³.

In the element region 61, the semiconductor device according to the first preferred embodiment includes not only the semiconductor substrate 25, but also an emitter-side element trench structure, an emitter-side interlayer film 11, an emitter electrode 12, a collector-side element trench structure, a collector-side interlayer film 15, and a collector electrode 16.

The emitter-side element trench structure is disposed on the front surface side of the semiconductor substrate 25, and includes an emitter-side gate insulating film 9 and an emitter-side gate electrode 10. A trench that penetrates the p-type base layer 3 and the emitter-side n-type layer 4 from the n-type source layer 1 and reaches the n-type drift layer 5 is formed on the front surface side of the semiconductor substrate 25. The emitter-side gate insulating film 9 formed with an oxide film, for example, is disposed in the trench formed on the front surface side.

The emitter-side gate electrode 10 is disposed over the trench on the front surface side via the emitter-side gate insulating film 9. Note that, in FIG. 1, the emitter-side element trench structure (the emitter-side gate insulating film 9 and the emitter-side gate electrode 10) is illustrated in a simplified manner.

As illustrated in FIG. 3, the emitter electrode 12 as a principal electrode portion is disposed on the front surface side of the semiconductor substrate 25. The emitter-side interlayer film 11 is disposed between the emitter-side gate electrode 10 and the emitter electrode 12, and insulates the emitter-side gate electrode 10 and the emitter electrode 12 from each other. Note that, as illustrated in FIG. 3, the positions of the end portions of the emitter electrode 12 substantially correspond to the positions of the end portions of the element region 61, and the region of the emitter electrode 12 substantially corresponds to the element region 61 in the planar view in FIG. 1.

When a voltage positive relative to the emitter electrode 12 is applied to the emitter-side gate electrode 10 of the emitter-side element trench structure, a channel electrically connecting the n-type source layer 1 and the withstand-voltage holding portion (the n-type drift layer 5) is formed in the p-type base layer 3. Accordingly, the n-type source layer 1, the p-type base layer 3, and the emitter-side element trench structure (the emitter-side gate insulating film 9 and the emitter-side gate electrode 10) constitute an element region emitter-side MOS channel portion in which a MOS channel can be formed on the front surface side of the semiconductor substrate 25.

The collector-side element trench structure is disposed on the back surface side of the semiconductor substrate 25, and includes a collector-side gate insulating film 13 and a collector-side gate electrode 14 shown in FIG. 3. A trench that penetrates the p-type collector layer 7 from the collector-side n-type layer 8 and reaches the n-type buffer layer 6 is formed on the back surface side of the semiconductor substrate 25. The collector-side gate insulating film 13 formed with an oxide film, for example, is disposed in the trench formed on the back surface side.

The collector-side gate electrode 14 is disposed over the trench on the back surface side via the collector-side gate insulating film 13. Note that, in FIG. 2, the collector-side element trench structure (the collector-side gate insulating film 13 and the collector-side gate electrode 14) is illustrated in a simplified manner. The intervals (emitter-side gate pitch) at which the emitter-side gate electrode 10 is repeatedly disposed, and the intervals (collector-side gate pitch) at which the collector-side gate electrode 14 is repeatedly disposed may be the same or different.

As illustrated in FIG. 3, the collector electrode 16 as a principal electrode portion is disposed on the back surface side of the semiconductor substrate 25. The collector-side interlayer film 15 is disposed between the collector-side gate electrode 14 and the collector electrode 16, and insulates the collector-side gate electrode 14 and the collector electrode 16 from each other.

When a voltage positive relative to the collector electrode 16 is applied to the collector-side gate electrode 14 of the collector-side element trench structure, a channel electrically connecting the collector-side n-type layer 8 and the n-type buffer layer 6 is formed in the p-type collector layer 7. Accordingly, the collector-side n-type layer 8, the p-type collector layer 7, and the collector-side element trench structure (the collector-side gate insulating film 13 and the collector-side gate electrode 14) constitute an element region collector-side MOS channel portion in which a MOS channel can be formed on the back surface side of the semiconductor substrate 25.

### Termination Region 62

In the termination region 62, the semiconductor substrate 25 includes the n-type drift layer 5, the n-type buffer layer 6, the p-type collector layer 7, a p-type well layer 17, and an n-type channel stopper layer 18. The n-type drift layer 5, the n-type buffer layer 6, and the p-type collector layer 7 in the termination region 62 are the same as the n-type drift layer 5, the n-type buffer layer 6, and the p-type collector layer 7 in the element region 61.

The p-type well layer 17 and the n-type channel stopper layer 18 are selectively disposed on the front surface side of the n-type drift layer 5, which is a withstand-voltage holding portion. For example, the peak concentration of the p-type impurity in the p-type well layer 17 is not lower than about 10¹⁶ cm⁻³ and not higher than about 10¹⁸ cm⁻³. For example, the peak concentration of the n-type impurity in the n-type channel stopper layer 18 is not lower than about 10¹⁸ cm⁻³ and not higher than about 10²¹ cm⁻³.

In the element region 61, the semiconductor device according to the first preferred embodiment includes not only the semiconductor substrate 25, but also the emitter-side interlayer film 11, the emitter electrode 12, the collector-side interlayer film 15, the collector electrode 16, a field plate 19, an emitter-side passivation film 20, an emitter-side gate wiring line 21, a collector-side gate wiring line 22, an emitter-side gate pad 23 in FIG. 1, a collector-side gate pad 24, and a collector-side gate leak preventing portion.

The emitter-side interlayer film 11 has a contact hole for exposing the p-type well layer 17 and the n-type channel stopper layer 18. The p-type well layer 17 closest to the element region 61 is connected to the emitter electrode 12 via the contact hole of the emitter-side interlayer film 11. Each of the other p-type well layers 17 and the n-type channel stopper layer 18 is connected to the field plate 19 via the contact hole of the emitter-side interlayer film 11.

The emitter-side gate wiring line 21 is insulated from the emitter electrode 12, the p-type well layer 17, and the field plate 19 by the emitter-side interlayer film 11 and the emitter-side passivation film 20, but is connected to the emitter-side gate electrode 10 in a cross-section different from that shown in FIG. 3. The emitter-side gate pad 23 in FIG. 1 is insulated from the emitter electrode 12, but is electrically connected to the emitter-side gate electrode 10 via the emitter-side gate wiring line 21 in a cross-section different from that shown in FIG. 3. The emitter-side gate pad 23 is connected to a bonding wire (not shown), so that the emitter-side gate electrode 10 is electrically connected to the outside.

The collector-side gate wiring line 22 is insulated from the p-type collector layer 7 and the collector electrode 16 by the collector-side interlayer film 15, but is connected to the collector-side gate electrode 14 in a cross-section different from that shown in FIG. 3. The collector-side gate pad 24 in FIG. 2 is insulated from the collector electrode 16, but is electrically connected to the collector-side gate electrode 14 via the collector-side gate wiring line 22. The collector-side gate pad 24 is connected to a collector-side gate lead frame (not shown) by solder (not shown), so that the collector-side gate electrode 14 is electrically connected to the outside. Note that, as illustrated in FIG. 2, a side surface of the semiconductor substrate 25 and the collector electrode 16 surround the collector-side gate pad 24 in a planar view.

The collector-side gate leak preventing portion is a collector-side terminal trench structure in the first preferred embodiment. The collector-side terminal trench structure is disposed on the back surface side of the semiconductor substrate 25, and includes a collector-side terminal insulating film 30 and a collector-side terminal electrode 31 shown in FIG. 3. A trench that penetrates the p-type collector layer 7 and reaches the n-type buffer layer 6 is formed on the back surface side of the semiconductor substrate 25. The collector-side terminal insulating film 30 formed with an oxide film, for example, is disposed in the trench formed on the back surface side.

The collector-side terminal electrode 31 is disposed over the trench on the back surface side via the collector-side terminal insulating film 30. The collector-side terminal electrode 31 may be connected to the collector electrode 16, or may be connected to a floating electrode (not shown). Note that, in FIG. 2, the collector-side terminal trench structure (the collector-side terminal insulating film 30 and the collector-side terminal electrode 31) is illustrated in a simplified manner, like the collector-side element trench structure (the collector-side gate insulating film 13 and the collector-side gate electrode 14).

As shown in FIG. 3, in a cross-sectional view, the collector-side terminal trench structure (the collector-side terminal insulating film 30 and the collector-side terminal electrode 31) penetrates the p-type collector layer 7 on a side surface side of the semiconductor substrate 25, with respect to the connecting portion 16a between the collector electrode 16 and the p-type collector layer 7. In the first preferred embodiment, the collector-side terminal trench structure penetrates the p-type collector layer 7 at a side surface of the semiconductor substrate 25 in a cross-sectional view.

### Summary of the First Preferred Embodiment

With the above configuration, when a voltage positive relative to the emitter electrode 12 is applied to the emitter-side gate electrode 10 via the emitter-side gate pad 23, the n-type source layer 1 is electrically connected to the withstand-voltage holding portion (the n-type drift layer 5) by the emitter-side MOS channel. As a result, the IGBT enters an on-state. On the other hand, when the application of the positive voltage to the emitter-side gate pad 23 is stopped, the IGBT is turned off.

At a time of turnoff, when a voltage positive relative to the collector electrode 16 is applied to the collector-side gate electrode 14 via the collector-side gate pad 24, the collector-side n-type layer 8 is electrically connected to the n-type buffer layer 6 by the collector-side MOS channel. The hole injection efficiency of the p-type collector layer 7 then drops accordingly, and thus, the current can be shut off at high speed.

However, there is a case where solder (not shown) disposed between the collector-side gate pad 24 and the collector-side gate lead frame (not shown) flows around to the side surface of the semiconductor substrate 25 during the manufacturing process. In this case, by a conventional technology, a current path different from the regular current path, or specifically, a path extending from the collector-side gate lead frame to the collector electrode 16 via the solder and the p-type collector layer 7 is formed between the collector-side gate lead frame and the collector electrode 16. As a result, there is a problem in that the leakage current of the collector-side gate increases.

In the first preferred embodiment, on the other hand, the collector-side terminal trench structure (the collector-side terminal insulating film 30 and the collector-side terminal electrode 31) penetrates the p-type collector layer 7 on a side surface side of the semiconductor substrate 25, with respect to the connecting portion 16a between the collector electrode 16 and the p-type collector layer 7. With this arrangement, the p-type collector layer 7 around the collector-side gate pad 24 is insulated so that the collector-side terminal trench structure blocks the current path. Thus, even in a case where the solder between the collector-side gate pad 24 and the collector-side gate lead frame flows around to the side surface of the semiconductor substrate 25, an increase in leakage current of the collector-side gate can be prevented.

### Second Preferred Embodiment

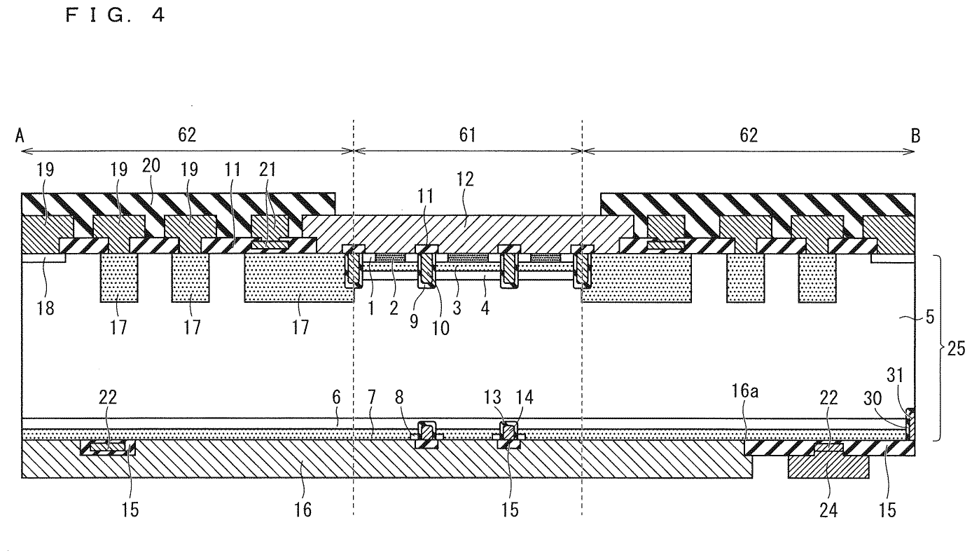

FIG. 4 is a cross-sectional view illustrating the configuration of a semiconductor device according to a second preferred embodiment. In the first preferred embodiment, the depth of the collector-side terminal trench structure is the same as the depth of the collector-side element trench structure.

In the second preferred embodiment, on the other hand, the depth of the collector-side terminal trench structure (the collector-side terminal insulating film 30 and the collector-side terminal electrode 31) is greater than the depth of the collector-side element trench structure (the collector-side gate insulating film 13 and the collector-side gate electrode 14). In FIG. 4, as an example, the trench of the collector-side terminal trench structure penetrates the p-type collector layer 7 and the n-type buffer layer 6, and reaches the n-type drift layer 5. With such a configuration, the insulation properties of the p-type collector layer 7 around the collector-side gate pad 24 can be enhanced, and thus, an increase in leakage current of the collector-side gate can be further prevented.

### Third Preferred Embodiment

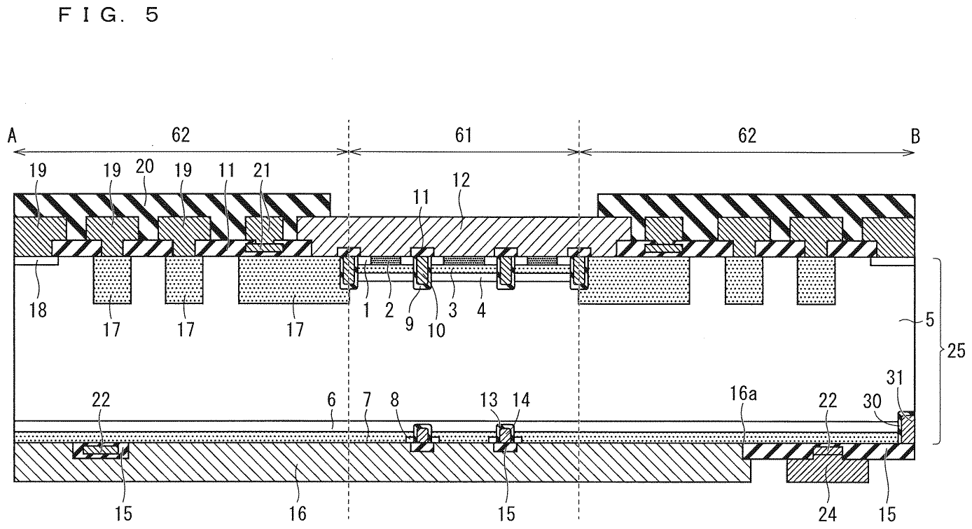

FIG. 5 is a cross-sectional view illustrating the configuration of a semiconductor device according to a third preferred embodiment. In the third preferred embodiment, the width of the collector-side terminal trench structure (the collector-side terminal insulating film 30 and the collector-side terminal electrode 31) is greater than the width of the collector-side element trench structure (the collector-side gate insulating film 13 and the collector-side gate electrode 14). With such a configuration, the insulation properties of the p-type collector layer 7 around the collector-side gate pad 24 can be enhanced by the collector-side terminal trench structure, and thus, an increase in leakage current of the collector-side gate can be further prevented.

Further, even under the same etching conditions, a trench having a greater width normally has a greater depth. Therefore, according to the third preferred embodiment, even if the trench of the collector-side terminal trench structure and the trench of the collector-side element trench structure are formed in the same process, the depth of the collector-side terminal trench structure would be greater than the depth of the collector-side element trench structure. Thus, the configuration of the second preferred embodiment can be achieved without any additional process.

### Fourth Preferred Embodiment

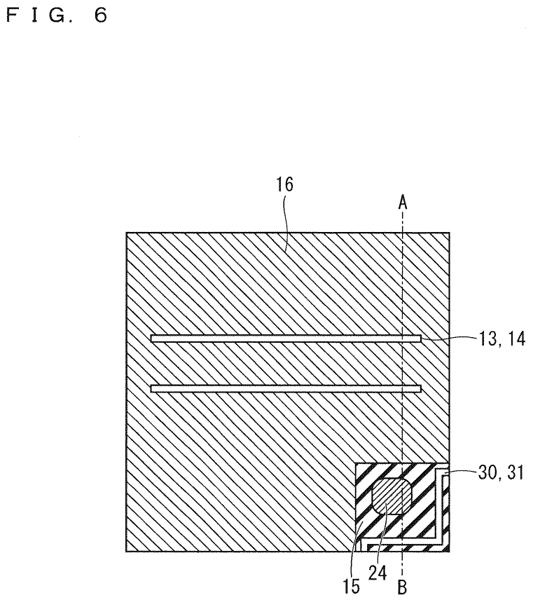

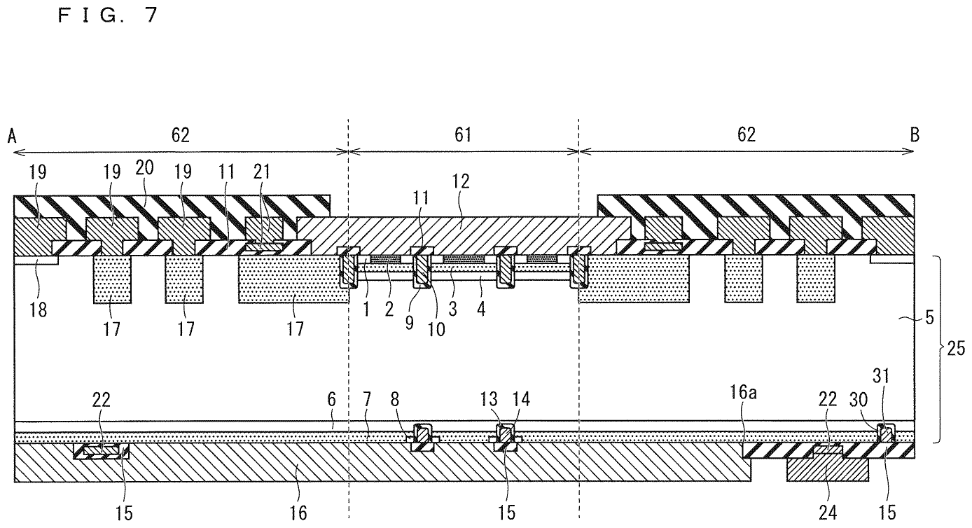

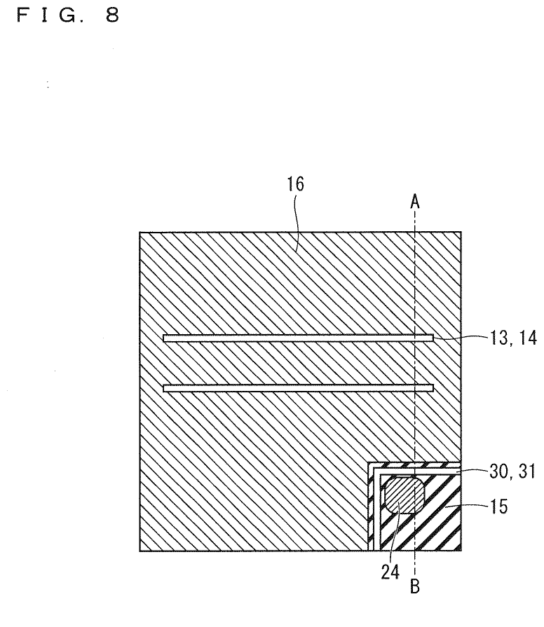

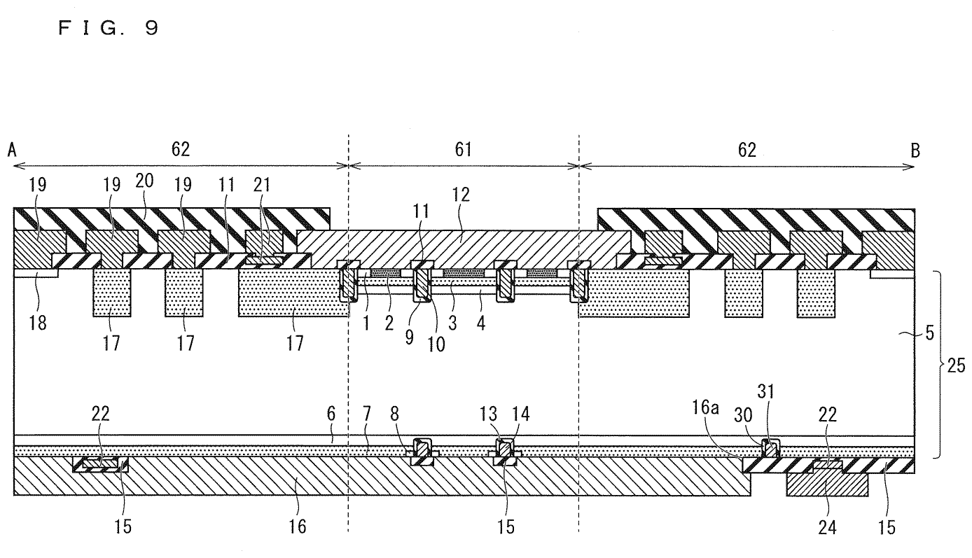

FIG. 6 is a plan view illustrating a configuration of the back side of a semiconductor device according to a fourth preferred embodiment, and FIG. 7 is a cross-sectional view taken along the line A-B defined in FIG. 6. FIG. 8 is a plan view illustrating another configuration of the back side of a semiconductor device according to the fourth preferred embodiment, and FIG. 9 is a cross-sectional view taken along the line A-B defined in FIG. 8.

In the first preferred embodiment, the collector-side terminal trench structure penetrates the p-type collector layer 7 at a side surface of the semiconductor substrate 25 in a cross-sectional view. In the fourth preferred embodiment, on the other hand, the collector-side terminal trench structure penetrates the p-type collector layer 7 on the side of the connecting portion 16a with respect to a side surface of the semiconductor substrate 25 in a cross-sectional view. That is, in a cross-sectional view, the collector-side terminal trench structure penetrates the p-type collector layer 7 at a portion other than the side surface of the semiconductor substrate 25, and insulates the p-type collector layer 7 on the side of the connecting portion 16a from the p-type collector layer 7 on the side of the side surface of the semiconductor substrate 25.

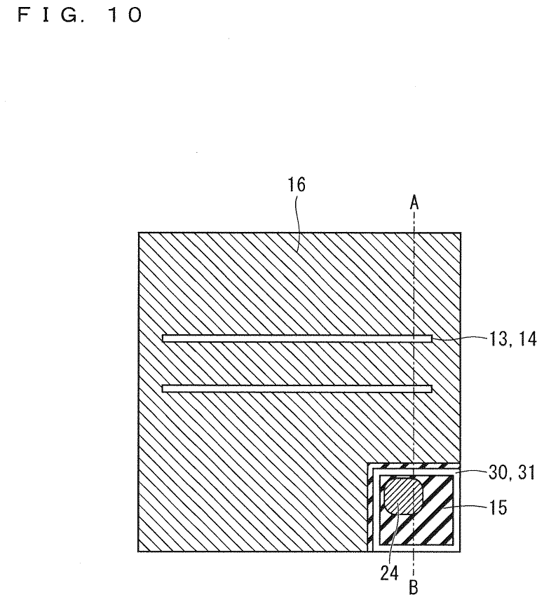

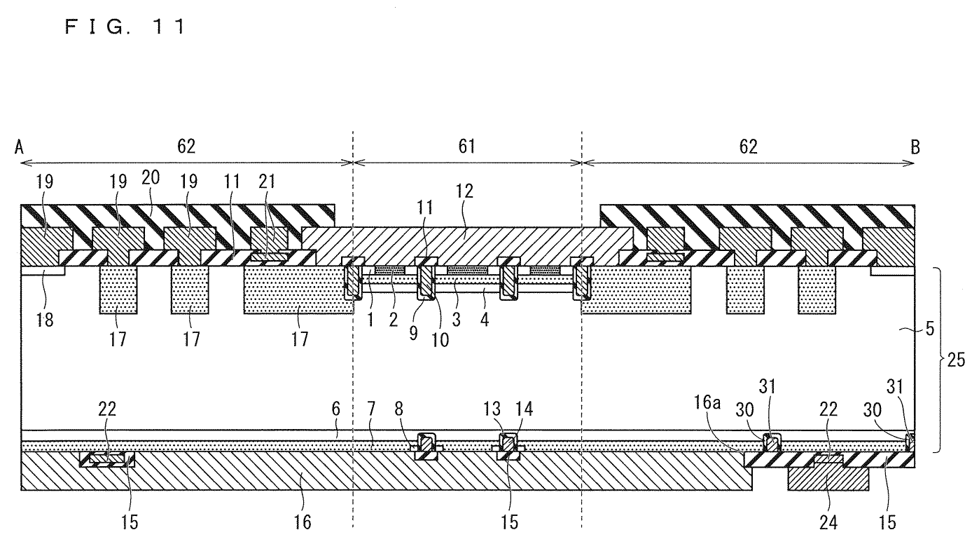

With such a configuration, dicing-induced damage to the collector-side terminal trench structure that prevents an increase in leakage current of the collector-side gate can be suppressed. Note that, as illustrated in FIGS. 10 and 11, a collector-side terminal trench structure that is a combination of the first preferred embodiment and the fourth preferred embodiment may be disposed on the back surface side of the semiconductor substrate 25.

### Fifth Preferred Embodiment

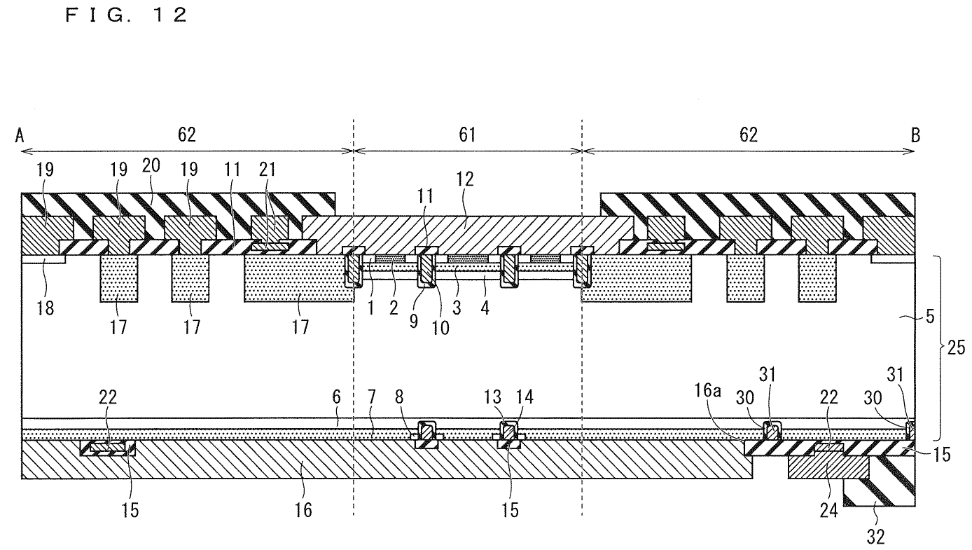

FIG. 12 is a cross-sectional view illustrating the configuration of a semiconductor device according to a fifth preferred embodiment. In the fifth preferred embodiment, a collector-side passivation film 32 that is a passivation film is disposed on the back surface side of the semiconductor substrate 25. The collector-side passivation film 32 is disposed on the collector-side gate pad 24 on a side surface side of the semiconductor substrate 25.

With such a structure, the collector-side passivation film 32 can prevent the solder between the collector-side gate pad 24 and the collector-side gate lead frame from flowing around to the side surface of the semiconductor substrate 25. Thus, even if an abnormality occurs in any of the collector-side terminal trench structure and the collector-side passivation film 32, an increase in leakage current of the collector-side gate can be prevented.

### Sixth Preferred Embodiment

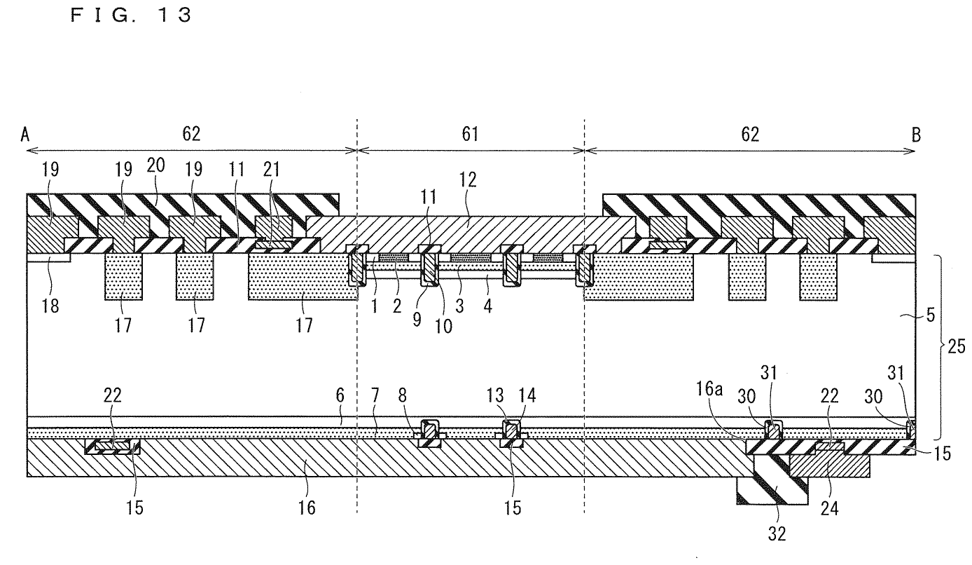

FIG. 13 is a cross-sectional view illustrating the configuration of a semiconductor device according to a sixth preferred embodiment. In the sixth preferred embodiment, a collector-side passivation film 32 that is a passivation film is disposed on the back surface side of the semiconductor substrate 25, as in the fifth preferred embodiment. In the sixth preferred embodiment, however, the collector-side passivation film 32 is disposed on the collector-side gate pad 24 on the side of the collector electrode 16.

With such a structure, the collector-side passivation film 32 can prevent the solder between the collector-side gate pad 24 and the collector-side gate lead frame from reaching the collector electrode 16. Thus, it is possible to prevent formation of a current path (a path extending from the collector-side gate lead frame to the collector electrode 16 via the solder) that would increase leakage current in the collector-side gate, and is different from the current path described in the first preferred embodiment.

### Seventh Preferred Embodiment

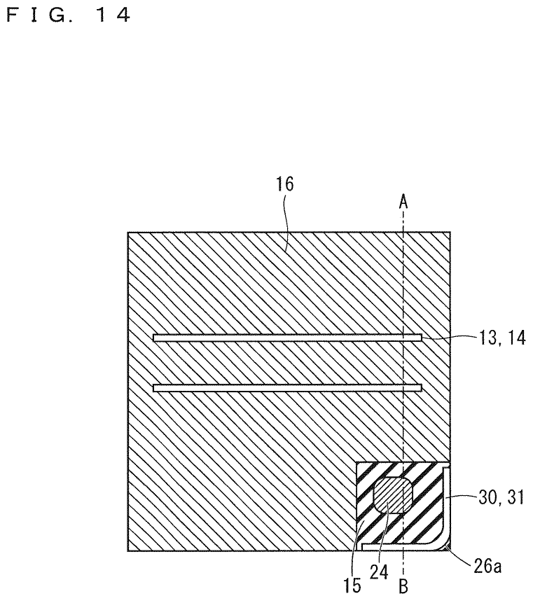

FIG. 14 is a plan view illustrating the configuration of the back side of a semiconductor device according to a seventh preferred embodiment. In the seventh preferred embodiment, in the collector-side terminal trench structure (the collector-side terminal insulating film 30 and the collector-side terminal electrode 31), a trench corner portion 26a corresponding to a corner portion of the semiconductor substrate 25 is rounded in a planar view. With such a configuration, the load to be applied to the trench corner portion 26a of the collector-side terminal trench structure at the time of dicing can be reduced, and thus, dicing-induced damage to the trench corner portion 26a can be suppressed.

### Eighth Preferred Embodiment

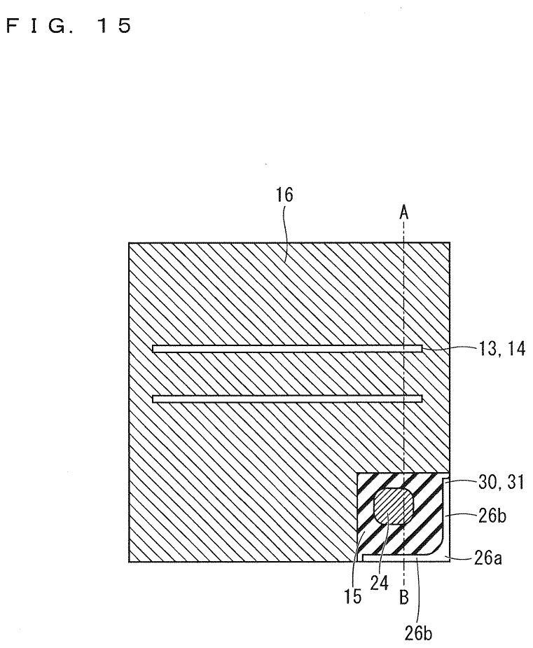

FIG. 15 is a plan view illustrating the configuration of the back side of a semiconductor device according to an eighth preferred embodiment. In the eighth preferred embodiment, in a planar view, the width of the trench corner portion 26a that is of the collector-side terminal trench structure and corresponds to a corner portion of the semiconductor substrate 25 is greater than the width of a linear portion 26b that is of the collector-side terminal trench structure and is connected to the trench corner portion 26a. With such a configuration, the load to be applied to the trench corner portion 26a of the collector-side terminal trench structure at the time of dicing can be reduced, and thus, dicing-induced damage to the trench corner portion 26a can be suppressed.

### Ninth Preferred Embodiment

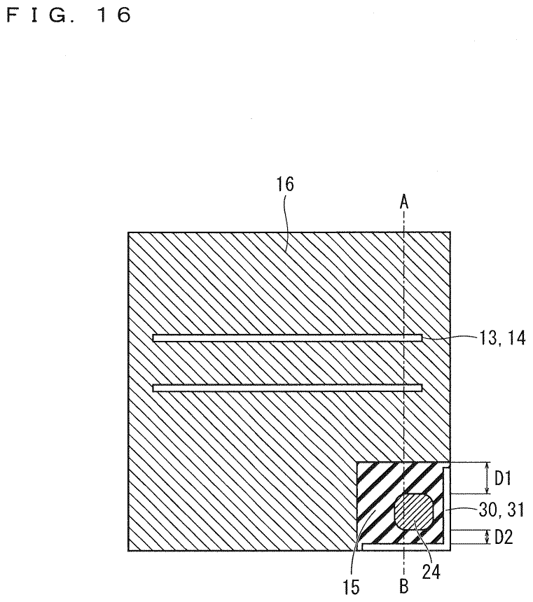

FIG. 16 is a plan view illustrating the configuration of the back side of a semiconductor device according to a ninth preferred embodiment. In the ninth preferred embodiment, in a planar view, a distance D1 between the collector-side gate pad 24 and the collector electrode 16 is longer than a distance D2 between the collector-side gate pad 24 and a side surface of the semiconductor substrate 25.

With such a configuration, the collector-side gate pad 24 is disposed near the side surface of the semiconductor substrate 25 in a planar view, but an increase in leakage current of the collector-side gate can be prevented by the collector-side terminal trench structure. Meanwhile, the collector-side gate pad 24 is separated further from the collector electrode 16, and thus, the solder between the collector-side gate pad 24 and the collector-side gate lead frame is prevented from reaching the collector electrode 16. Thus, it is possible to prevent formation of a current path (a path extending from the collector-side gate lead frame to the collector electrode 16 via the solder) that would increase leakage current in the collector-side gate.

### Tenth Preferred Embodiment

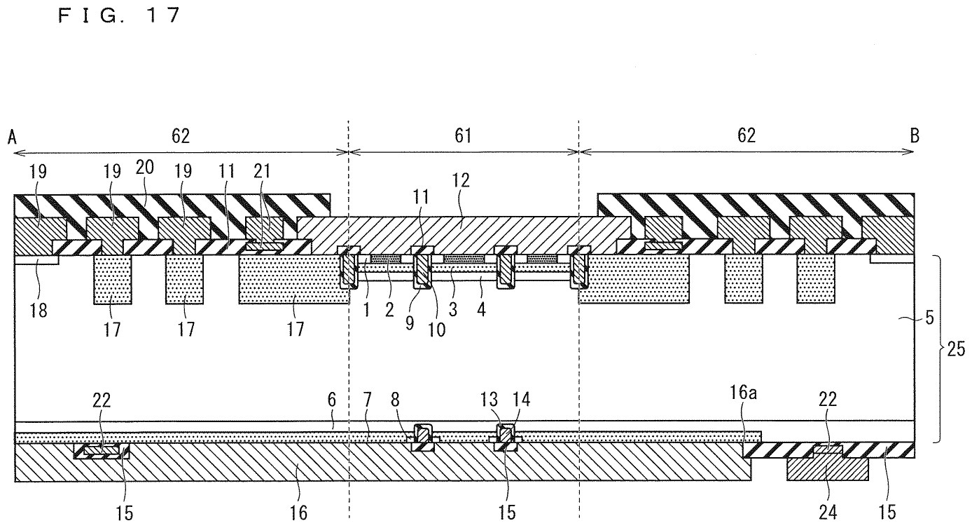

FIG. 17 is a cross-sectional view illustrating the configuration of a semiconductor device according to a tenth preferred embodiment. In the tenth preferred embodiment, the collector-side terminal trench structure is not adopted, and part of the n-type buffer layer 6 functions as the collector-side gate leak preventing portion. Specifically, in a cross-sectional view, the n-type buffer layer 6 penetrates the p-type collector layer 7 on a side surface side of the semiconductor substrate 25 with respect to the connecting portion 16a between the collector electrode 16 and the p-type collector layer 7. In FIG. 17, as an example of that, the n-type buffer layer 6 is disposed, instead of the p-type collector layer 7, in almost the entire region on the side surface side of the semiconductor substrate 25 with respect to the connecting portion 16a.

With such a configuration, the current path extending from a side surface of the semiconductor substrate 25 around the collector-side gate pad 24 to the collector electrode 16 passes through a p-type semiconductor via an n-type semiconductor, and accordingly, the current path includes a portion that has a reverse bias of a pn junction. Thus, even in a case where the solder between the collector-side gate pad 24 and the collector-side gate lead frame flows around to the side surface of the semiconductor substrate 25, an increase in leakage current of the collector-side gate can be prevented.

### Eleventh Preferred Embodiment

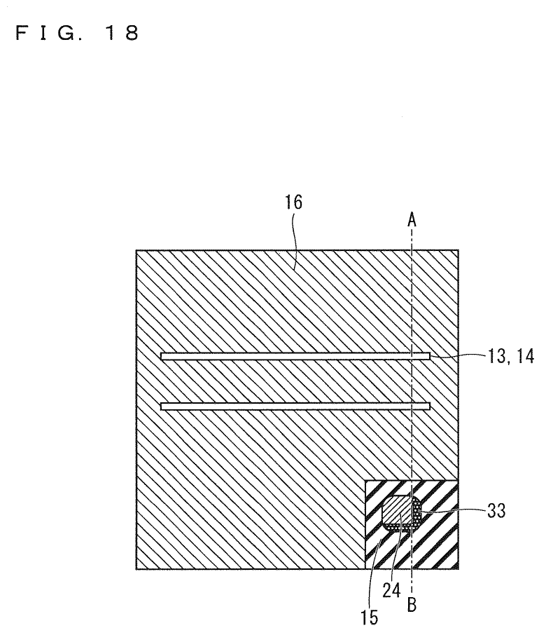

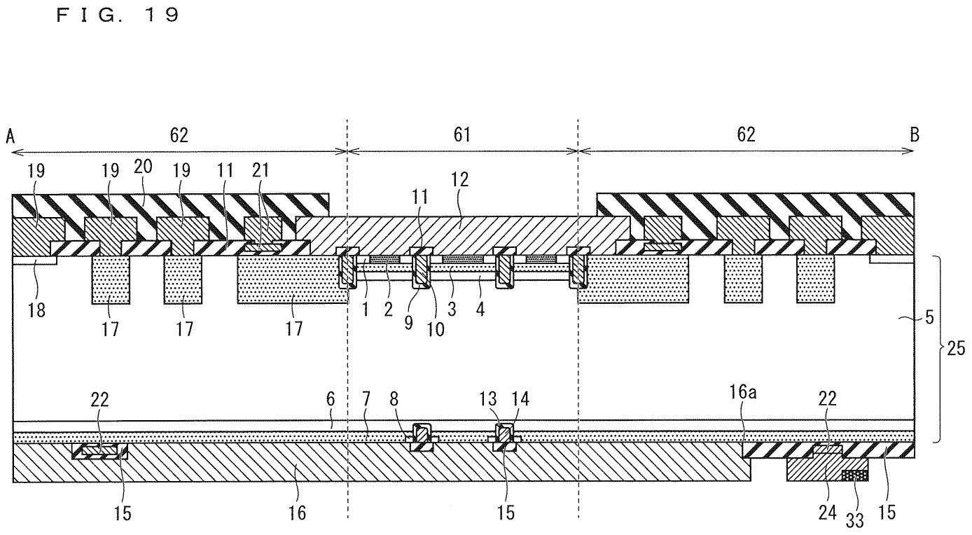

FIG. 18 is a plan view illustrating the configuration of the back side of a semiconductor device according to an eleventh preferred embodiment, and FIG. 19 is a cross-sectional view illustrating the configuration of the semiconductor device according to the eleventh preferred embodiment. In the eleventh preferred embodiment, a modified layer 33 is provided without penetrating the p-type collector layer 7, which differs from the configurations of the first and tenth preferred embodiments in which the p-type collector layer 7 is penetrated.

The modified layer 33 is disposed in a portion of the surface of the collector-side gate pad 24 in a cross-sectional view, and has lower solder wettability than that of the rest of the surface. In the eleventh preferred embodiment, the portion in which the modified layer 33 is disposed includes a portion of the collector-side gate pad 24 on a side surface side of the semiconductor substrate 25.

The modified layer 33 is at least one of an oxidized layer on the surface of the collector-side gate pad 24 or a roughened layer on the surface of the collector-side gate pad 24. Note that, in the present specification, at least one of A, B, C, . . . , or Z means any one of all combinations that can be obtained by extracting one or more from the group consisting of A, B, C, . . . , and Z, for example.

Both the oxidized layer and the roughened layer have lower solder wettability than that of a regular layer. In a case where a laser modification process is used as the process of forming the modified layer 33, for example, both oxidizing and roughening are performed, and therefore, the modified layer 33 formed by the laser modification process includes both an oxidized layer and a roughened layer.

With the configuration as described above, the solder of the collector-side gate pad 24 can be prevented from flowing around to the side surface of the semiconductor substrate 25 by the modified layer 33 having low solder wettability, and thus, an increase in leakage current of the collector-side gate can be prevented.

### Twelfth Preferred Embodiment

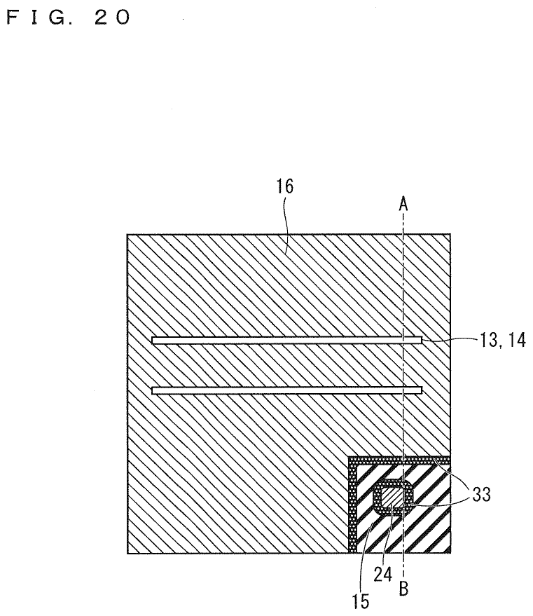

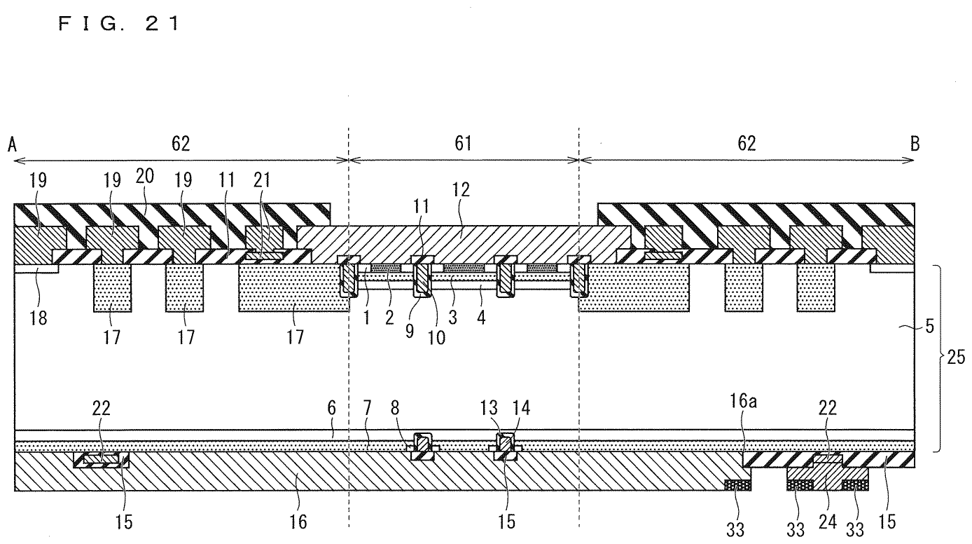

FIG. 20 is a plan view illustrating the configuration of the back side of a semiconductor device according to a twelfth preferred embodiment, and FIG. 21 is a cross-sectional view illustrating the configuration of the semiconductor device according to the twelfth preferred embodiment. In the twelfth preferred embodiment, the modified layer 33 is provided as in the eleventh preferred embodiment. In the twelfth preferred embodiment, the modified layer 33 is disposed in a portion of a surface of at least one of the collector-side gate pad 24 and the collector electrode 16 in a cross-sectional view.

In the example in FIGS. 20 and 21, the modified layer 33 is disposed in a portion of the surface of the collector-side gate pad 24 in a cross-sectional view. The portion includes a portion of the collector-side gate pad 24 on a side surface side of the semiconductor substrate 25 and a portion of the collector-side gate pad 24 on the side of the collector electrode 16.

With such a configuration, the solder of the collector-side gate pad 24 can be prevented from flowing around to a side surface of the semiconductor substrate 25 by the modified layer 33 in the collector-side gate pad 24 on the side surface side of the semiconductor substrate 25, and thus, an increase in leakage current of the collector-side gate can be prevented.

Furthermore, the solder of the collector-side gate pad 24 can be prevented from reaching the collector electrode 16 by the modified layer 33 in the collector-side gate pad 24 on the side of the collector electrode 16. Thus, it is possible to prevent formation of a current path that would increase leakage current in the collector-side gate.

Also, in the example in FIGS. 20 and 21, the modified layer 33 is disposed in a portion of the surface of the collector electrode 16 in a cross-sectional view. The portion includes at least a portion of an outer peripheral portion of the collector electrode 16 in a planar view.

With such a configuration, the solder of the collector electrode 16 can be prevented from flowing around to a side surface of the semiconductor substrate 25 or reaching the collector-side gate pad 24, by the modified layer 33 disposed in at least a portion of the outer peripheral portion of the collector electrode 16. Thus, an increase in leakage current of the collector-side gate can be prevented.

### Thirteenth Preferred Embodiment

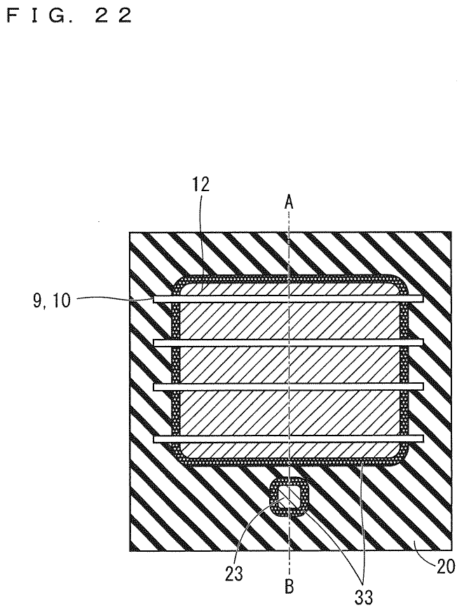

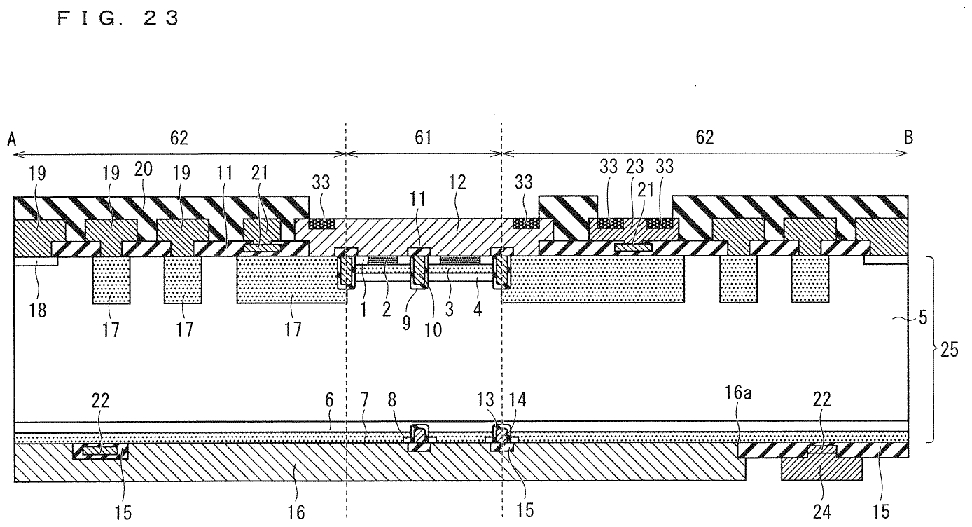

FIG. 22 is a plan view illustrating a configuration of the front side of a semiconductor device according to a thirteenth preferred embodiment, and FIG. 23 is a cross-sectional view taken along the line A-B defined in FIG. 22. In the thirteenth preferred embodiment, the modified layer 33 is provided as in the eleventh preferred embodiment. In the thirteenth preferred embodiment, the modified layer 33 is disposed in a portion of a surface of at least one of the emitter-side gate pad 23 and the emitter electrode 12 in a cross-sectional view.

In the example in FIGS. 22 and 23, the modified layer 33 is disposed in a portion of the surface of the emitter-side gate pad 23 in a cross-sectional view. The portion includes a portion of the emitter-side gate pad 23 on a side surface side of the semiconductor substrate 25 and a portion of the emitter-side gate pad 23 on the side of the emitter electrode 12.

With such a configuration, the solder of the emitter-side gate pad 23 can be prevented from flowing around to a side surface of the semiconductor substrate 25 by the modified layer 33 in the emitter-side gate pad 23 on the side surface side of the semiconductor substrate 25, and thus, an increase in leakage current of the emitter-side gate can be prevented.

Furthermore, the solder of the emitter-side gate pad 23 can be prevented from reaching the emitter electrode 12 by the modified layer 33 in the emitter-side gate pad 23 on the side of the emitter electrode 12. Thus, it is possible to prevent formation of a current path that would increase leakage current in the emitter-side gate.

Also, in the example in FIGS. 22 and 23, the modified layer 33 is disposed in a portion of the surface of the emitter electrode 12 in a cross-sectional view. The portion includes at least a portion of an outer peripheral portion of the emitter electrode 12 in a planar view.

With such a configuration, the solder of the emitter electrode 12 can be prevented from flowing around to a side surface of the semiconductor substrate 25 or reaching the emitter-side gate pad 23, by the modified layer 33 disposed in at least a portion of the outer peripheral portion of the emitter electrode 12. Thus, an increase in leakage current of the emitter-side gate can be prevented.

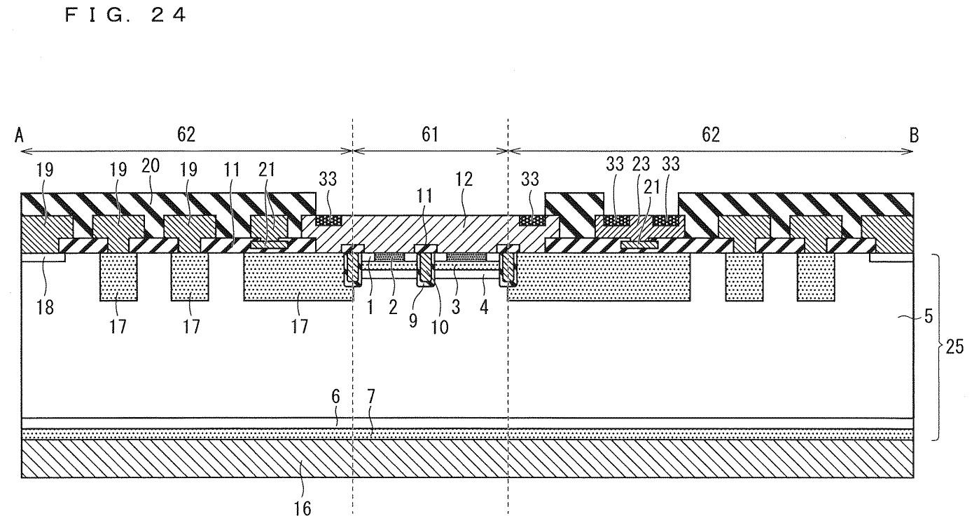

Note that, in the configuration illustrated in FIG. 23, the collector-side element trench structure (the collector-side gate insulating film 13 and the collector-side gate electrode 14) and the collector-side gate pad 24 are disposed on the back surface side of the semiconductor substrate 25. However, the semiconductor device according to the thirteenth preferred embodiment is not limited to the configuration illustrated in FIG. 23, and the collector-side element trench structure and the collector-side gate pad 24 are not necessarily provided, as in a configuration illustrated in FIG. 24.

Note that, in the present disclosure in English, “a” and “an” each mean “one or more”. Accordingly, “a”, “an”, “one or more” and “at least one” can be used interchangeably.

Note that the preferred embodiments and the modifications can be freely combined, and each preferred embodiment and each modification can be modified or omitted as appropriate.

In the following, various modes of the present disclosure are collectively described as Appendixes.
(Appendix 1)

A semiconductor device comprising:
a semiconductor substrate having a front surface and a back surface on which an element region and a termination region surrounding the element region are defined;
an emitter electrode disposed on the front surface side of the semiconductor substrate;
an emitter-side element trench structure that is disposed on the front surface side of the semiconductor substrate in the element region, and includes an emitter-side gate electrode insulated from the emitter electrode;
an emitter-side gate pad that is disposed on the front surface side of the semiconductor substrate in the termination region, is insulated from the emitter electrode, and is electrically connected to the emitter-side gate electrode;
a collector electrode disposed on the back surface side of the semiconductor substrate;
a collector-side element trench structure that is disposed on the back surface side of the semiconductor substrate in the element region, and includes a collector-side gate electrode insulated from the collector electrode;
a collector-side gate pad that is disposed on the back surface side of the semiconductor substrate in the termination region, is insulated from the collector electrode, and is electrically connected to the collector-side gate electrode; and
a collector-side terminal trench structure that is disposed on the back surface side of the semiconductor substrate in the termination region, and includes a collector-side terminal electrode, wherein
the semiconductor substrate includes:
a drift layer of a first conductivity type;
a buffer layer of the first conductivity type that is disposed on the back surface side of the drift layer; and
a collector layer of a second conductivity type that is disposed on the back surface side of the buffer layer,
in a planar view, a side surface of the semiconductor substrate and the collector electrode surround the collector-side gate pad, and,
in a cross-sectional view, the collector-side terminal trench structure penetrates the collector layer on the side surface side of the semiconductor substrate with respect to a connecting portion between the collector electrode and the collector layer.
(Appendix 2)

The semiconductor device according to Appendix 1, wherein,
in a cross-sectional view, the collector-side terminal trench structure penetrates the collector layer at the side surface of the semiconductor substrate.
(Appendix 3)

The semiconductor device according to Appendix 1 or 2, wherein
a depth of the collector-side terminal trench structure is greater than a depth of the collector-side element trench structure.
(Appendix 4)

The semiconductor device according to any one of Appendixes 1 to 3, wherein
a width of the collector-side terminal trench structure is greater than a width of the collector-side element trench structure.
(Appendix 5)

The semiconductor device according to Appendix 1, wherein,
in a cross-sectional view, the collector-side terminal trench structure penetrates the collector layer on the connecting portion side with respect to the side surface of the semiconductor substrate.
(Appendix 6)

The semiconductor device according to any one of Appendixes 1 to 5, further comprising
a passivation film that is disposed on the back surface side of the semiconductor substrate, and on the collector-side gate pad on the side surface side of the semiconductor substrate.
(Appendix 7)

The semiconductor device according to any one of Appendixes 1 to 5, further comprising
a passivation film that is disposed on the back surface side of the semiconductor substrate, and on the collector-side gate pad on the collector electrode side.
(Appendix 8)

The semiconductor device according to Appendix 2, wherein,
in a planar view, a trench corner portion of the collector-side terminal trench structure is rounded, the trench corner portion corresponding to a corner portion of the semiconductor substrate.
(Appendix 9)

The semiconductor device according to Appendix 2, wherein,
in a planar view, a width of a trench corner portion of the collector-side terminal trench structure is greater than a width of a linear portion of the collector-side terminal trench structure, the trench corner portion corresponding to a corner portion of the semiconductor substrate, the linear portion being connected to the trench corner portion.
(Appendix 10)

The semiconductor device according to any one of Appendixes 1 to 9, wherein,
in a planar view, a distance between the collector-side gate pad and the collector electrode is longer than a distance between the collector-side gate pad and the side surface of the semiconductor substrate.
(Appendix 11)

A semiconductor device comprising:
a semiconductor substrate having a front surface and a back surface on which an element region and a termination region surrounding the element region are defined;
an emitter electrode disposed on the front surface side of the semiconductor substrate;
an emitter-side element trench structure that is disposed on the front surface side of the semiconductor substrate in the element region, and includes an emitter-side gate electrode insulated from the emitter electrode;
an emitter-side gate pad that is disposed on the front surface side of the semiconductor substrate in the termination region, is insulated from the emitter electrode, and is electrically connected to the emitter-side gate electrode;
a collector electrode disposed on the back surface side of the semiconductor substrate;
a collector-side element trench structure that is disposed on the back surface side of the semiconductor substrate in the element region, and includes a collector-side gate electrode insulated from the collector electrode; and
a collector-side gate pad that is disposed on the back surface side of the semiconductor substrate in the termination region, is insulated from the collector electrode, and is electrically connected to the collector-side gate electrode, wherein
the semiconductor substrate includes:
a drift layer of a first conductivity type;
a buffer layer of the first conductivity type that is disposed on the back surface side of the drift layer; and
a collector layer of a second conductivity type that is disposed on the back surface side of the buffer layer,
in a planar view, a side surface of the semiconductor substrate and the collector electrode surround the collector-side gate pad, and,
in a cross-sectional view, the buffer layer penetrates the collector layer on the side surface side of the semiconductor substrate with respect to a connecting portion between the collector electrode and the collector layer.
(Appendix 12)

A semiconductor device comprising:
a semiconductor substrate having a front surface and a back surface on which an element region and a termination region surrounding the element region are defined;
an emitter electrode disposed on the front surface side of the semiconductor substrate;
an emitter-side element trench structure that is disposed on the front surface side of the semiconductor substrate in the element region, and includes an emitter-side gate electrode insulated from the emitter electrode;
an emitter-side gate pad that is disposed on the front surface side of the semiconductor substrate in the termination region, is insulated from the emitter electrode, and is electrically connected to the emitter-side gate electrode;
a collector electrode disposed on the back surface side of the semiconductor substrate;
a collector-side element trench structure that is disposed on the back surface side of the semiconductor substrate in the element region, and includes a collector-side gate electrode insulated from the collector electrode; and
a collector-side gate pad that is disposed on the back surface side of the semiconductor substrate in the termination region, is insulated from the collector electrode, and is electrically connected to the collector-side gate electrode, wherein
the semiconductor substrate includes:
a drift layer of a first conductivity type;
a buffer layer of the first conductivity type that is disposed on the back surface side of the drift layer; and
a collector layer of a second conductivity type that is disposed on the back surface side of the buffer layer, and
the semiconductor device further comprises a modified layer that is disposed in a portion of a surface of at least one of the collector-side gate pad or the collector electrode in a cross-sectional view, and has lower solder wettability than solder wettability of a remaining portion of the surface.
(Appendix 13)

The semiconductor device according to Appendix 12, wherein
the portion in which the modified layer is disposed includes a portion of the collector-side gate pad on a side surface side of the semiconductor substrate.
(Appendix 14)

The semiconductor device according to Appendix 12 or 13, wherein
the portion in which the modified layer is disposed includes a portion of the collector-side gate pad on the collector electrode side.
(Appendix 15)

The semiconductor device according to any one of Appendixes 12 to 14, wherein
the portion in which the modified layer is disposed includes at least a portion of an outer peripheral portion of the collector electrode in a planar view.
(Appendix 16)

A semiconductor device comprising:
a semiconductor substrate having a front surface and a back surface on which an element region and a termination region surrounding the element region are defined;
an emitter electrode disposed on the front surface side of the semiconductor substrate;
an emitter-side element trench structure that is disposed on the front surface side of the semiconductor substrate in the element region, and includes an emitter-side gate electrode insulated from the emitter electrode; and
an emitter-side gate pad that is disposed on the front surface side of the semiconductor substrate in the termination region, is insulated from the emitter electrode, and is electrically connected to the emitter-side gate electrode, wherein
the semiconductor device further comprises a modified layer that is disposed in a portion of a surface of at least one of the emitter-side gate pad or the emitter electrode in a cross-sectional view, and has lower solder wettability than solder wettability of a remaining portion of the surface.
(Appendix 17)

The semiconductor device according to Appendix 16, wherein
the portion in which the modified layer is disposed includes a portion of the emitter-side gate pad on a side surface side of the semiconductor substrate.
(Appendix 18)

The semiconductor device according to Appendix 16 or 17, wherein
the portion in which the modified layer is disposed includes a portion of the emitter-side gate pad on the emitter electrode side.
(Appendix 19)

The semiconductor device according to any one of Appendixes 16 to 18, wherein
the portion in which the modified layer is disposed includes at least a portion of an outer peripheral portion of the emitter electrode in a planar view.
(Appendix 20)

The semiconductor device according to any one of Appendixes 12 to 19, wherein
the modified layer is at least one of an oxidized layer of the surface or a roughened layer of the surface.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate having a front surface and a back surface on which an element region and a termination region surrounding the element region are defined;
an emitter electrode disposed on the front surface side of the semiconductor substrate;
an emitter-side element trench structure that is disposed on the front surface side of the semiconductor substrate in the element region, and includes an emitter-side gate electrode insulated from the emitter electrode;
an emitter-side gate pad that is disposed on the front surface side of the semiconductor substrate in the termination region, is insulated from the emitter electrode, and is electrically connected to the emitter-side gate electrode;
a collector electrode disposed on the back surface side of the semiconductor substrate;
a collector-side element trench structure that is disposed on the back surface side of the semiconductor substrate in the element region, and includes a collector-side gate electrode insulated from the collector electrode;
a collector-side gate pad that is disposed on the back surface side of the semiconductor substrate in the termination region, is insulated from the collector electrode, and is electrically connected to the collector-side gate electrode; and
a collector-side terminal trench structure that is disposed on the back surface side of the semiconductor substrate in the termination region, and includes a collector-side terminal electrode, wherein
the semiconductor substrate includes:
a drift layer of a first conductivity type;
a buffer layer of the first conductivity type that is disposed on the back surface side of the drift layer; and
a collector layer of a second conductivity type that is disposed on the back surface side of the buffer layer,
in a planar view, a side surface of the semiconductor substrate and the collector electrode surround the collector-side gate pad, and,
in a cross-sectional view, the collector-side terminal trench structure penetrates the collector layer on the side surface side of the semiconductor substrate with respect to a connecting portion between the collector electrode and the collector layer.

2. The semiconductor device according to claim 1, wherein,
in a cross-sectional view, the collector-side terminal trench structure penetrates the collector layer at the side surface of the semiconductor substrate.

3. The semiconductor device according to claim 1, wherein
a depth of the collector-side terminal trench structure is greater than a depth of the collector-side element trench structure.

4. The semiconductor device according to claim 1, wherein
a width of the collector-side terminal trench structure is greater than a width of the collector-side element trench structure.

5. The semiconductor device according to claim 1, wherein,
in a cross-sectional view, the collector-side terminal trench structure penetrates the collector layer on the connecting portion side with respect to the side surface of the semiconductor substrate.

6. The semiconductor device according to claim 1, further comprising
a passivation film that is disposed on the back surface side of the semiconductor substrate, and on the collector-side gate pad on the side surface side of the semiconductor substrate.

7. The semiconductor device according to claim 1, further comprising
a passivation film that is disposed on the back surface side of the semiconductor substrate, and on the collector-side gate pad on the collector electrode side.

8. The semiconductor device according to claim 2, wherein,
in a planar view, a trench corner portion of the collector-side terminal trench structure is rounded, the trench corner portion corresponding to a corner portion of the semiconductor substrate.

9. The semiconductor device according to claim 2, wherein,
in a planar view, a width of a trench corner portion of the collector-side terminal trench structure is greater than a width of a linear portion of the collector-side terminal trench structure, the trench corner portion corresponding to a corner portion of the semiconductor substrate, the linear portion being connected to the trench corner portion.

10. The semiconductor device according to claim 1, wherein,
in a planar view, a distance between the collector-side gate pad and the collector electrode is longer than a distance between the collector-side gate pad and the side surface of the semiconductor substrate.

11. A semiconductor device comprising:
a semiconductor substrate having a front surface and a back surface on which an element region and a termination region surrounding the element region are defined;
an emitter electrode disposed on the front surface side of the semiconductor substrate;
an emitter-side element trench structure that is disposed on the front surface side of the semiconductor substrate in the element region, and includes an emitter-side gate electrode insulated from the emitter electrode;
an emitter-side gate pad that is disposed on the front surface side of the semiconductor substrate in the termination region, is insulated from the emitter electrode, and is electrically connected to the emitter-side gate electrode;
a collector electrode disposed on the back surface side of the semiconductor substrate;
a collector-side element trench structure that is disposed on the back surface side of the semiconductor substrate in the element region, and includes a collector-side gate electrode insulated from the collector electrode; and
a collector-side gate pad that is disposed on the back surface side of the semiconductor substrate in the termination region, is insulated from the collector electrode, and is electrically connected to the collector-side gate electrode, wherein
the semiconductor substrate includes:
a drift layer of a first conductivity type;
a buffer layer of the first conductivity type that is disposed on the back surface side of the drift layer; and
a collector layer of a second conductivity type that is disposed on the back surface side of the buffer layer,
in a planar view, a side surface of the semiconductor substrate and the collector electrode surround the collector-side gate pad, and,
in a cross-sectional view, the buffer layer penetrates the collector layer on the side surface side of the semiconductor substrate with respect to a connecting portion between the collector electrode and the collector layer.

12. A semiconductor device comprising:
a semiconductor substrate having a front surface and a back surface on which an element region and a termination region surrounding the element region are defined;
an emitter electrode disposed on the front surface side of the semiconductor substrate;
an emitter-side element trench structure that is disposed on the front surface side of the semiconductor substrate in the element region, and includes an emitter-side gate electrode insulated from the emitter electrode;
an emitter-side gate pad that is disposed on the front surface side of the semiconductor substrate in the termination region, is insulated from the emitter electrode, and is electrically connected to the emitter-side gate electrode;
a collector electrode disposed on the back surface side of the semiconductor substrate;
a collector-side element trench structure that is disposed on the back surface side of the semiconductor substrate in the element region, and includes a collector-side gate electrode insulated from the collector electrode; and
a collector-side gate pad that is disposed on the back surface side of the semiconductor substrate in the termination region, is insulated from the collector electrode, and is electrically connected to the collector-side gate electrode, wherein
the semiconductor substrate includes:
a drift layer of a first conductivity type;
a buffer layer of the first conductivity type that is disposed on the back surface side of the drift layer; and
a collector layer of a second conductivity type that is disposed on the back surface side of the buffer layer, and
the semiconductor device further comprises a modified layer that is disposed in a portion of a surface of at least one of the collector-side gate pad or the collector electrode in a cross-sectional view, and has lower solder wettability than solder wettability of a remaining portion of the surface.

13. The semiconductor device according to claim 12, wherein
the portion in which the modified layer is disposed includes a portion of the collector-side gate pad on a side surface side of the semiconductor substrate.

14. The semiconductor device according to claim 12, wherein
the portion in which the modified layer is disposed includes a portion of the collector-side gate pad on the collector electrode side.

15. The semiconductor device according to claim 12, wherein
the portion in which the modified layer is disposed includes at least a portion of an outer peripheral portion of the collector electrode in a planar view.

16. A semiconductor device comprising:
a semiconductor substrate having a front surface and a back surface on which an element region and a termination region surrounding the element region are defined;
an emitter electrode disposed on the front surface side of the semiconductor substrate;
an emitter-side element trench structure that is disposed on the front surface side of the semiconductor substrate in the element region, and includes an emitter-side gate electrode insulated from the emitter electrode; and
an emitter-side gate pad that is disposed on the front surface side of the semiconductor substrate in the termination region, is insulated from the emitter electrode, and is electrically connected to the emitter-side gate electrode, wherein
the semiconductor device further comprises a modified layer that is disposed in a portion of a surface of at least one of the emitter-side gate pad or the emitter electrode in a cross-sectional view, and has lower solder wettability than solder wettability of a remaining portion of the surface.

17. The semiconductor device according to claim 16, wherein
the portion in which the modified layer is disposed includes a portion of the emitter-side gate pad on a side surface side of the semiconductor substrate.

18. The semiconductor device according to claim 16, wherein
the portion in which the modified layer is disposed includes a portion of the emitter-side gate pad on the emitter electrode side.

19. The semiconductor device according to claim 16, wherein
the portion in which the modified layer is disposed includes at least a portion of an outer peripheral portion of the emitter electrode in a planar view.

20. The semiconductor device according to claim 12, wherein
the modified layer is at least one of an oxidized layer of the surface or a roughened layer of the surface.
